(19) United States
(12) Patent Application Publication
(10) Pub. No.: US 2014/0151824 A1
(43) Pub. Date: Jun. 5, 2014

(54) SELF-ALIGNED WIRE FOR SPINTRONIC DEVICE

(71) Applicant: INTERNATIONAL BUSINESS MACHINES CORPORATION, (US)

(72) Inventors: David W. Abraham, Croton, NY (US); Philip L. Trouilloud, Norwood, NJ (US); Daniel C. Worledge, Cortlandt Manor, NY (US)

(73) Assignee: INTERNATIONAL BUSINESS MACHINES CORPORATION, Armonk, NY (US)

(21) Appl. No.: 13/689,850

(22) Filed: Nov. 30, 2012

(51) Int. Cl. H01L 29/82

(52) U.S. Cl. CPC H01L 29/82
USPC 257/421; 438/3

(57) ABSTRACT

A method for fabricating a spintronic cell includes forming a cavity in a substrate, forming a wire in the cavity, depositing a spacer layer over exposed portions of the substrate and the conductive field line, depositing a layer of conductive material on a portion of the spacer layer, removing portions of the layer of conductive material to define a conductive strap portion, wherein the conductive strap portion has a first distal region a second distal region and a medial region arranged therebetween, wherein the medial region has a cross sectional area that is less than a cross sectional area of the first distal region and a cross sectional area of the second distal region, and forming an spintronic device stack on the conductive strap portion above the conductive field line.

### FIELD OF INVENTION

The present invention relates generally to magnetic random access memory (MRAM) cells, and more specifically, to methods and systems involving providing increased current proximate to MRAM cells.

### DESCRIPTION OF RELATED ART

Magnetic random access memory devices often include magnetic materials that change states when an electric or magnetic field is applied to the devices. An array of MRAM devices may be used to store digital data. Examples of MRAM devices include thermally assisted MRAM and magnetic tunnel junction MRAM devices. Thermally assisted MRAM devices include a heating element that is operative to increase the temperature of the device during writing operations by passing current through the heating element. The increase in the temperature of the device affects the current of field needed to change the state of the device. The heating element can be the device itself.

In magnetic tunnel junction MRAM devices, a current may be passed proximate to the device to affect a magnetic field on the device. The current is used to affect the state of the device. The current path may include a conductive line or strip of conductive material.

### BRIEF SUMMARY

According to one embodiment of the present invention, a method for fabricating a spintronic cell includes forming a cavity in a substrate, forming a wire in the cavity, depositing a spacer layer over exposed portions of the substrate and the conductive field line, depositing a layer of conductive material on a portion of the spacer layer, removing portions of the layer of conductive material to define a conductive strap portion, wherein the conductive strap portion has a first distal region a second distal region and a medial region arranged therebetween, wherein the medial region has a cross sectional area that is less than a cross sectional area of the first distal region and a cross sectional area of the second distal region, and forming an spintronic device stack on the conductive strap portion above the conductive field line.

According to another embodiment of the present invention, a method for fabricating a spintronic cell includes forming a cavity in a substrate, forming a wire in the cavity, depositing a spacer layer over exposed portions of the substrate and the conductive field line, depositing a first insulator layer over the spacer layer, patterning and etching to remove portions of the first insulator layer to expose portions of the spacer layer and define a cavity in the first insulator layer, depositing a layer of conductive material in the cavity and over exposed portions of the first insulator layer, removing portions of the conductive material to expose portions of the insulator layer and the spacer layer, and define a first conductive strap portion and a second conductive strap portion, depositing a second layer of conductive material on exposed portions of the insulator layer, the spacer layer, the first conductive strap portion and the second conductive strap portion, patterning the second layer of conductive material to expose portions of the insulator layer, the first conductive strap portion and the second conductive strap portion; and to define a conductive connector portion that electrically connects the first conductive strap portion with the second conductive strap portion, and forming an spintronic device stack on the conductive connector portion above the conductive field line.

According to yet another embodiment of the present invention, a spintronic cell includes a substrate, a wire arranged on the substrate, a spacer layer disposed on the substrate and the conductive field line, a conductive strap portion arranged over a portion of the spacer layer, the conductive strap portion having a regions with a first cross sectional area above the wire and a second cross sectional area in regions of the wire that are above the substrate and extend outwardly from the region with the first cross sectional area, wherein the first cross sectional area is less than the second cross sectional area, and a spintronic device stack arranged on the conductive strap portion above the conductive field line.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a top view of a substrate and a photolithographic resist layer.

FIG. 2 illustrates a side view of FIG. 1.

FIG. 3 illustrates a side view of the resultant structure following the removal of exposed portions of the substrate.

FIG. 4 illustrates the resultant structure following the removal of the resist layer and the deposition of a conductive layer.

FIG. 5 illustrates the removal of a portion of the conductive layer.

FIG. 6 illustrates the removal of exposed portions of the substrate.

FIG. 7 illustrates a top view of FIG. 6.

FIG. 8 illustrates a side view of the resultant structure following the deposition of a spacer layer.

FIG. 9 illustrates the deposition of an insulator layer over the spacer layer.

FIG. 10 illustrates a side view following the deposition and patterning of a photolithographic resist layer.

FIG. 11 illustrates a top view of FIG. 10.

FIG. 12 illustrates a top view of the resultant structure following an etching process that removes exposed portions of the insulator layer.

FIG. 13 illustrates a top view of the resultant structure following the removal of the resist layer of FIG. 12.

FIG. 14 illustrates a top view of the deposition of a conductive layer.

FIG. 15 illustrates a top view of the resultant structure following a planarization process.

FIG. 16 illustrates a cut away view along the line 16 of FIG. 15.

FIG. 17 illustrates a cut away view along the line 17 of FIG. 15.

FIG. 18 illustrates the formation of an MRAM device stack on the conductive strap portion.

FIG. 19 illustrates a top view of FIG. 18.

FIG. 20 illustrates a top view of the resultant structure following the formation of a capping layer and a conductive electrode.

FIG. 21 illustrates a cut away view along the line 21 of FIG. 20.

FIG. 22 illustrates a cut away view along the line 22 of FIG. 20.

FIG. 23 illustrates a top view of the arrangement described in FIG. 14.

FIG. 24 illustrates a top view following a planarization process.

FIG. 25 illustrates a cut away view along the line 25 of FIG. 24.

FIG. 26 illustrates a top view of the resultant structure following the formation of a conductive connector portion.

FIG. 27 illustrates a cut away view along the line 27 of FIG. 26.

FIG. 28 illustrates a side view of the formation of an MRAM device stack on the conductive connector portion.

FIG. 29 illustrates a top view of FIG. 28.

FIG. 30 illustrates the resultant structure following the formation of a capping layer and a conductive electrode.

FIG. 31 illustrates an alternate exemplary embodiment of the conductive connector portion.

FIG. 32 illustrates an exemplary embodiment of an MRAM device stack.

FIG. 33 illustrates another exemplary embodiment of an MRAM device stack.

### DETAILED DESCRIPTION

As discussed above, it is often desirable to pass a current through a current path that is proximate to an MRAM device. However, if the current path includes a conductive line having a substantially uniform cross sectional area, a desired current density may not be achieved proximate to the MRAM device. In this regard, it is desirable to increase the current density of a conductive current path proximate to the MRAM device. The increase in the current density is achieved by reducing the relative cross sectional area of the current path proximate to the MRAM device. Such a reduction in the cross sectional area of the current path may be beneficial in for example, thermally assisted MRAM devices, since the reduction in the cross sectional area proximate to the MRAM device will increases the resistance in the regions having a reduced cross sectional area, the thermal energy output by the current path in the region having the increased resistance is increased. This heats the thermally assisted MRAM device more efficiently, particularly when low voltages are applied across the current path. The reduction of the cross sectional area of the current path is also beneficial in other types of spintronic devices which would benefit from a local increase in the spin current density. In this regard, the reduction of the cross sectional area proximate to a spintronic device increases the current density proximate to the spintronic device and may improve the performance of the spintronic device.

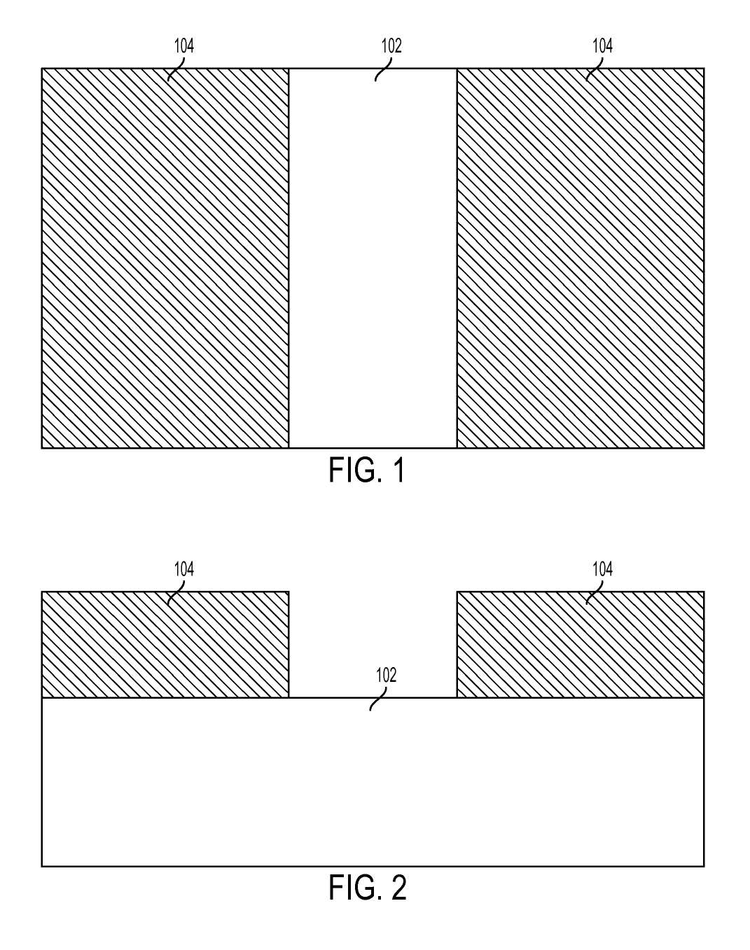

Methods for fabricating and the resultant structures of conductive lines proximate to MRAM cells are described below. Referring to FIG. 1, FIG. 1 illustrates a top view of a substrate 102 and a photolithographic resist layer 104 that is patterned on the substrate 102. The substrate 102 of the illustrated embodiment includes an insulator material such as a silicon oxide material. FIG. 2 illustrates a side view of FIG. 1.

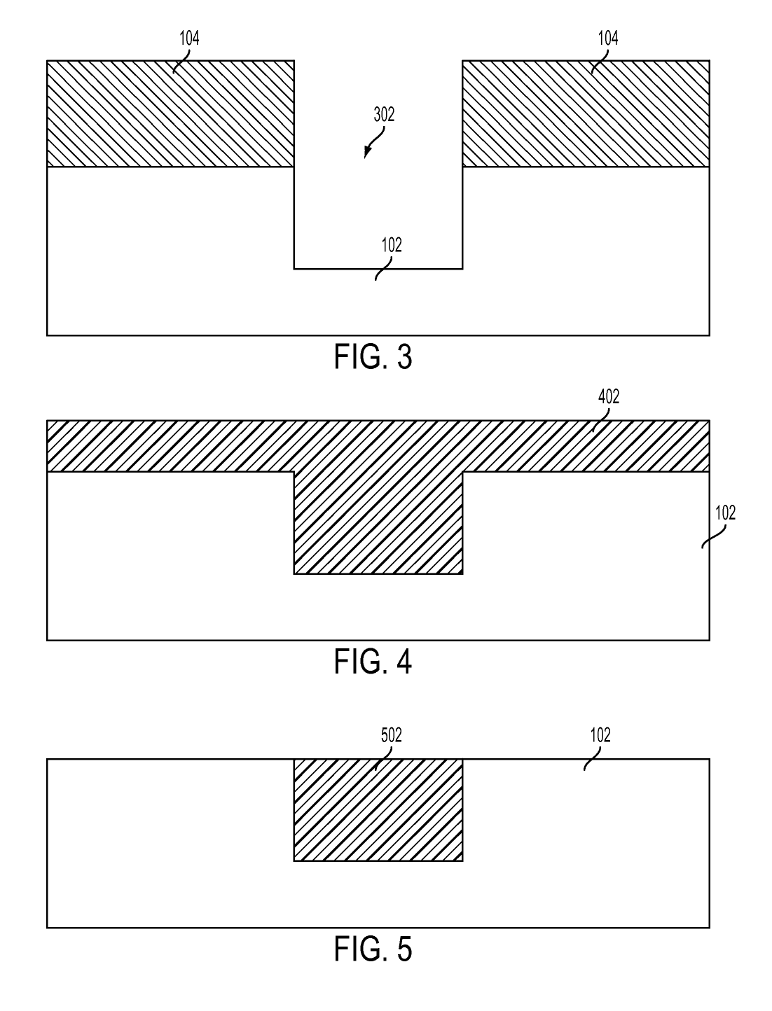

FIG. 3 illustrates a side view of the resultant structure following the removal of exposed portions of the substrate 102 to define a channel or cavity 302 in the substrate 102. An etching process such as, for example, an anisotropic etching process such as reactive ion etching (RIE) may be used to remove portions of the substrate 102.

FIG. 4 illustrates the resultant structure following the removal of the resist layer 104 and the deposition of a conductive layer 402 over exposed portions of the substrate 102 and in the cavity 302. The conductive layer 402 may include, for example, a conductive metal material such as Cu, Al, Au, or Ag. The conductive layer 402 may be deposited using any suitable deposition process such as, for example, chemical vapor deposition (CVD), plasma enhanced chemical vapor deposition (PECVD).

FIG. 5 illustrates the removal of a portion of the conductive layer 402 to expose portions of the substrate 102. The portions of the conductive layer 402 may be removed by, for example, a planarization process such as chemical mechanical polishing (CMP). The planarization process defines a field line 502 in the substrate 102 that fills the cavity 302 (of FIG. 3).

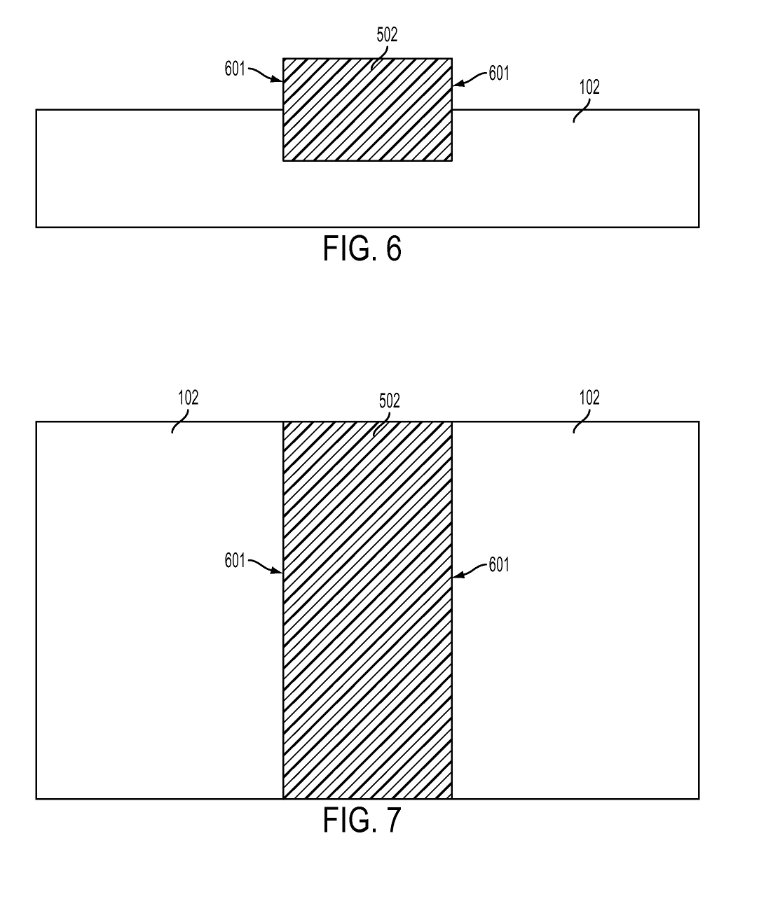

FIG. 6 illustrates the removal of exposed portions of the substrate 102. In this regard, a suitable etching process, such as for example, a chemical or sputter etching process that is selective to the field line 502 material is performed. The etching process recesses exposed portions of the substrate 102 without appreciably removing exposed portions of the field line 502. The etching process exposes portions of side walls 601 of the field line 502. FIG. 7 illustrates a top view of FIG. 6.

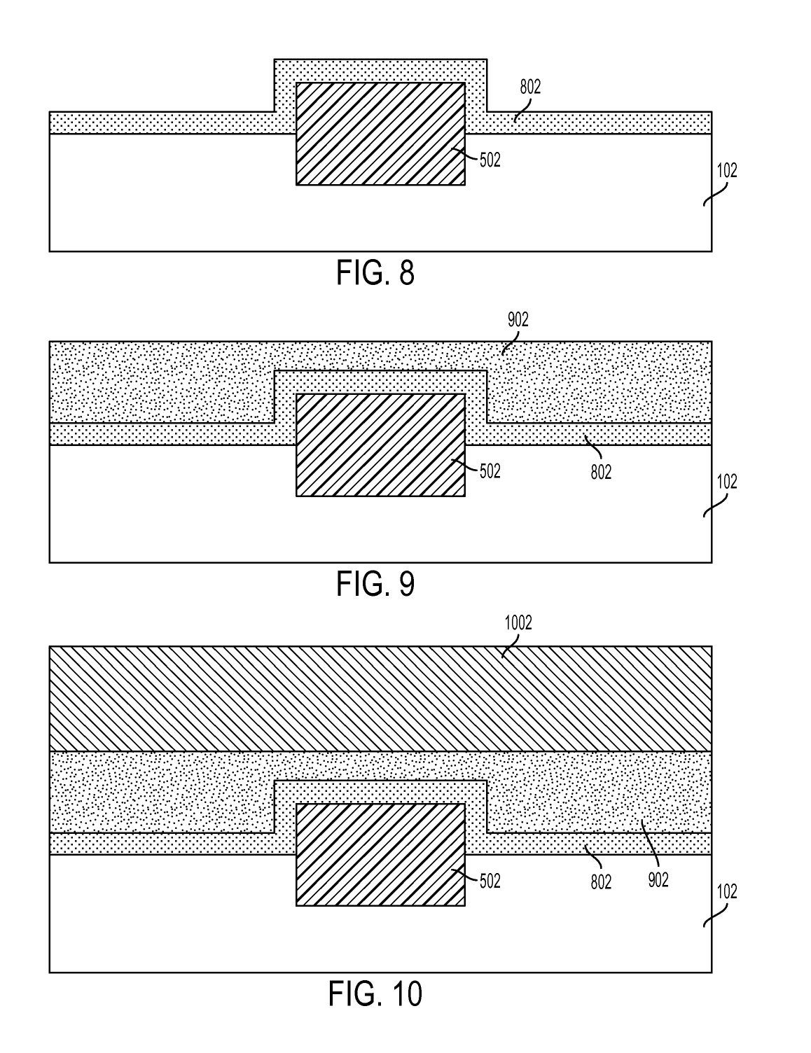

FIG. 8 illustrates a side view of the resultant structure following the deposition of a spacer layer 802 over exposed portions of the substrate 102 and conformally over the field line 502. The spacer layer 802 may include, for example, a nitride or an oxide material that may be deposited using a suitable deposition process.

FIG. 9 illustrates the deposition of an insulator layer 902 over the space layer 802. The insulator layer 902 may include, for example, a nitride or an oxide material that is planarized using for example, CMP. In the illustrated embodiment, the insulator layer 902 includes a material that is dissimilar to the spacer layer 802 material.

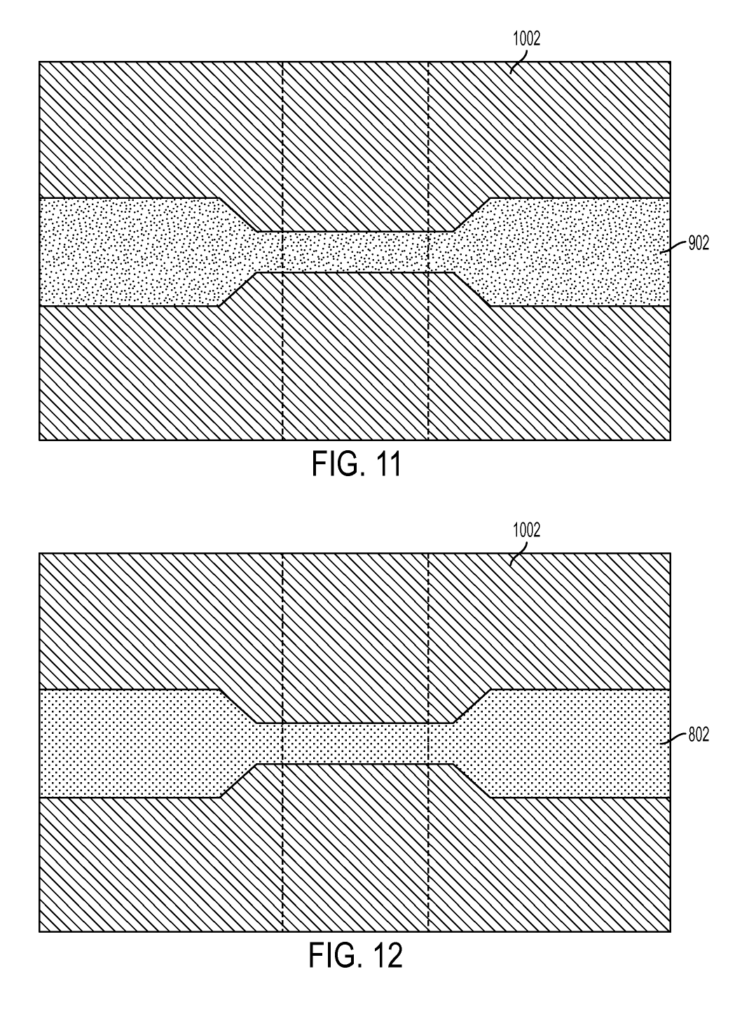

FIG. 10 illustrates a side view following the deposition and patterning of a photolithographic resist layer 1002 over the insulator layer 902. FIG. 11 illustrates a top view of FIG. 10.

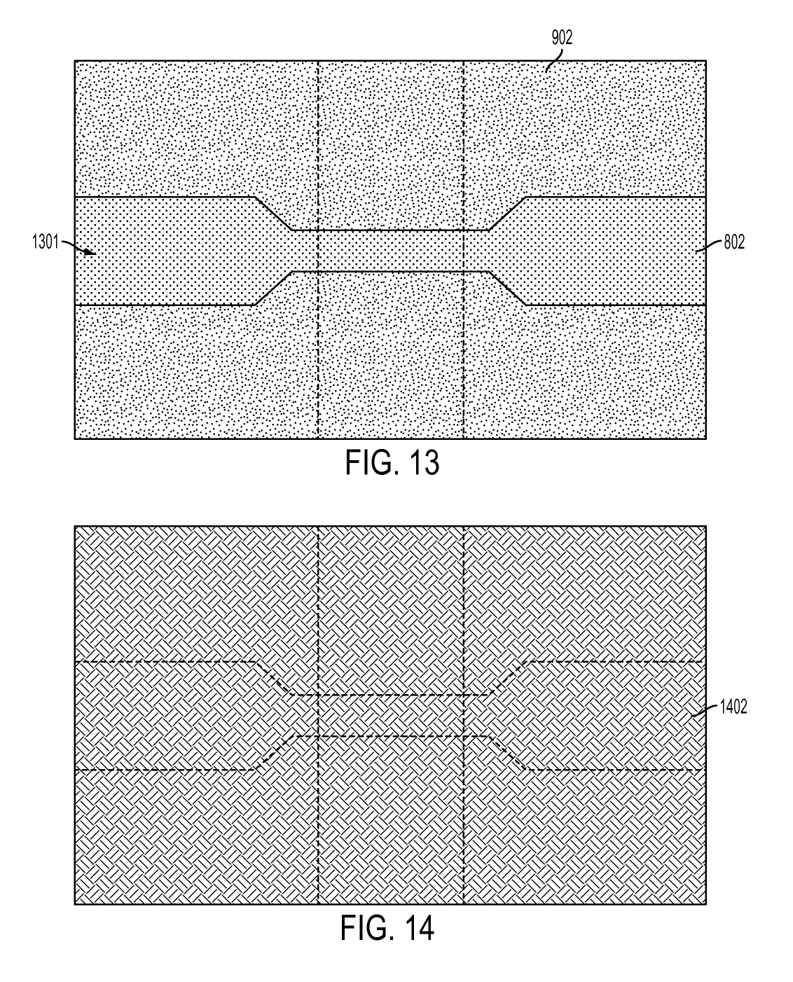

FIG. 12 illustrates a top view of the resultant structure following an etching process that removes exposed portions of the insulator layer 902 (of FIG. 11) and exposes portions of the spacer layer 802. The removal of the exposed portions of the insulator layer 902 forms a cavity 1301 in the insulator layer that is defined by the insulator layer 902 and the spacer layer 802. FIG. 13 illustrates a top view of the resultant structure following the removal of the resist layer 1002 (of FIG. 12).

FIG. 14 illustrates a top view of the deposition of a conductive layer 1402 over exposed portions of the spacer layer 802, in the cavity 1301 (of FIG. 13), and over exposed portions of the insulator layer 902. The conductive layer 1402 may include any conductive material such as, for example, Al, Cu, Ag, or Au.

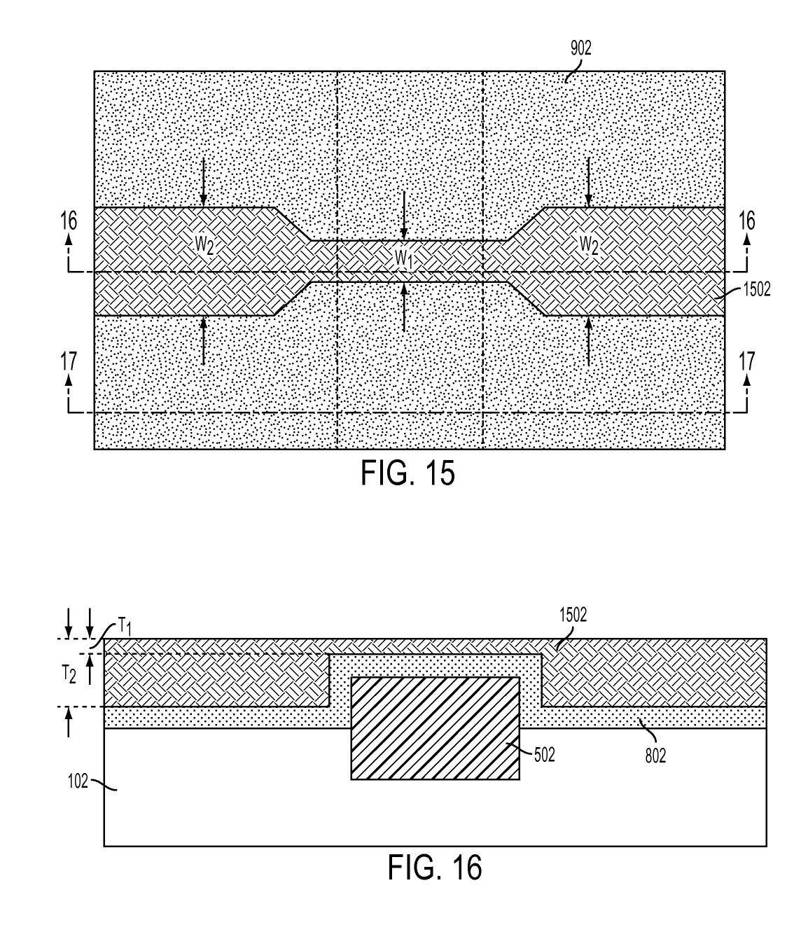

FIG. 15 illustrates a top view of the resultant structure following a planarization process such as, for example, CMP. The planarization process removes portions of the conductive layer 1402 to expose portions of the insulator layer 902. The removal of portions of the conductive layer 1402 defines a conductive strap portion 1502. The conductive strap portion 1502 has a width (WO above the field line 502 and a width (W₂) in distal regions above the substrate 102, where W₁<W₂.

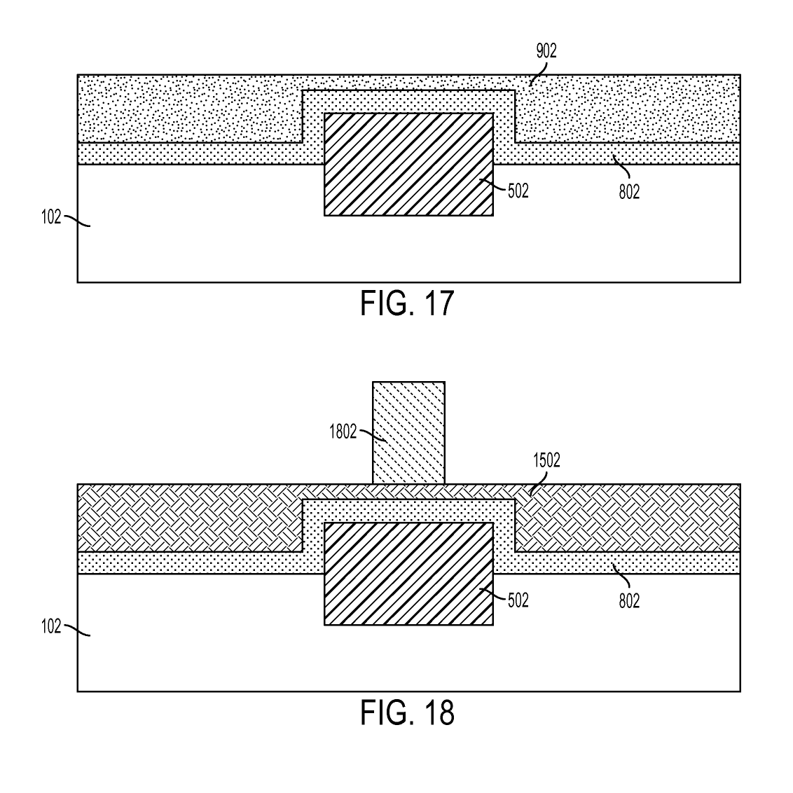

FIG. 16 illustrates a cut away view along the line 16 (of FIG. 15). The planarization process reduces the thickness of the conductive layer 1402 such that the conductive strap portion 1502 has a thickness (T₁) above the field line 502 and a thickness (T₂) in distal regions above the substrate 102, where T₁<T₂. The reduced thickness of the conductive strap portion 1502 above the field line 502 and the reduced width reduces the cross sectional area of the conductive strap portion 1502 above the field line 502. FIG. 17 illustrates a cut away view along the line 17 (of FIG. 15).

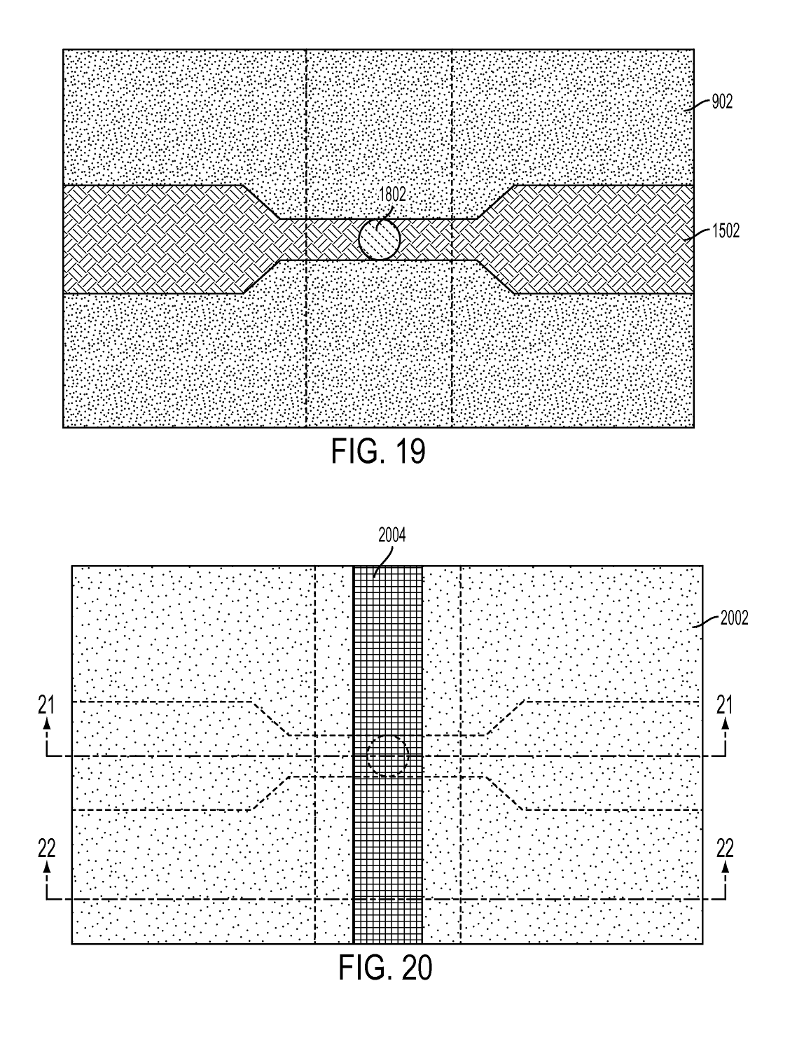

FIG. 18 illustrates the formation of an MRAM device stack 1802 on the conductive strap portion 1502. The MRAM device stack 1802 may be formed by, for example, the deposition and patterning of a plurality of layers of materials that form the MRAM device stack 1802. FIG. 19 illustrates a top view of FIG. 18. In this regard, exemplary embodiments of the MRAM device stack 1802 are described in further detail below in FIGS. 32 and 33. Though these figures describe two exemplary embodiments of MRAM device stacks 1802, any suitable MRAM device stack may be formed in the embodiments described herein.

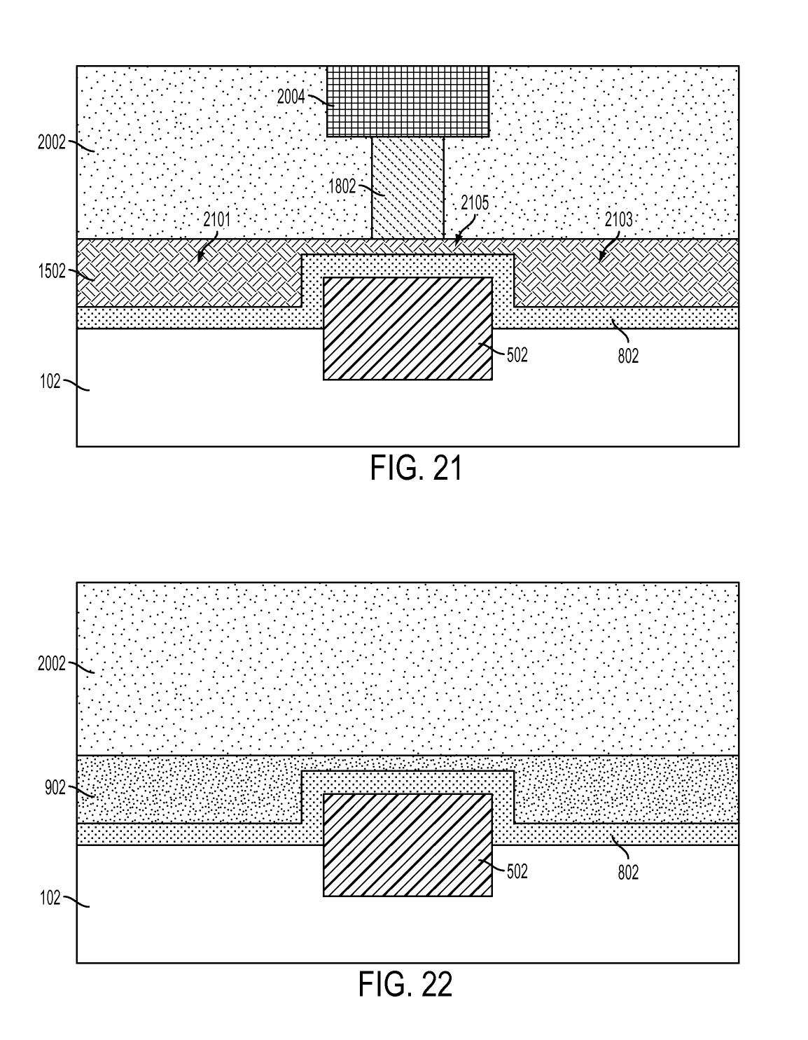

FIG. 20 illustrates a top view of the resultant structure following the formation of a capping layer 2002 and a conductive electrode 2004. The capping layer 2002 may include any suitable insulator material, such as, for example, a nitride or an oxide material that is deposited over exposed portions of the insulator layer 902, the conductive strap portion 1502, and the MRAM device stack 1802. A pattering, etching, and deposition process followed by a planarization process may be used to define the conductive electrode 2004. The conductive electrode 2004 is arranged in contact with the MRAM device stack 1802. FIG. 21 illustrates a cut away view along the line 21 (of FIG. 20). The device shown in FIG. 21 has a conductive strap portion 1502 having first and second distal regions 2101 and 2103 and a medial region 2105. The cross sectional area of the medial region 2015 is less than the cross sectional areas of the first and second distal regions 2101 and 2103. The MRAM device stack 1802 is arranged on the medial region 2105. FIG. 22 illustrates a cut away view along the line 22 (of FIG. 20) showing the arrangement of the capping layer 2002.

FIGS. 23-30 illustrate an alternate exemplary embodiment and method for fabricating an MRAM device. In this regard, FIG. 23 illustrates a top view of the arrangement described above in FIG. 14.

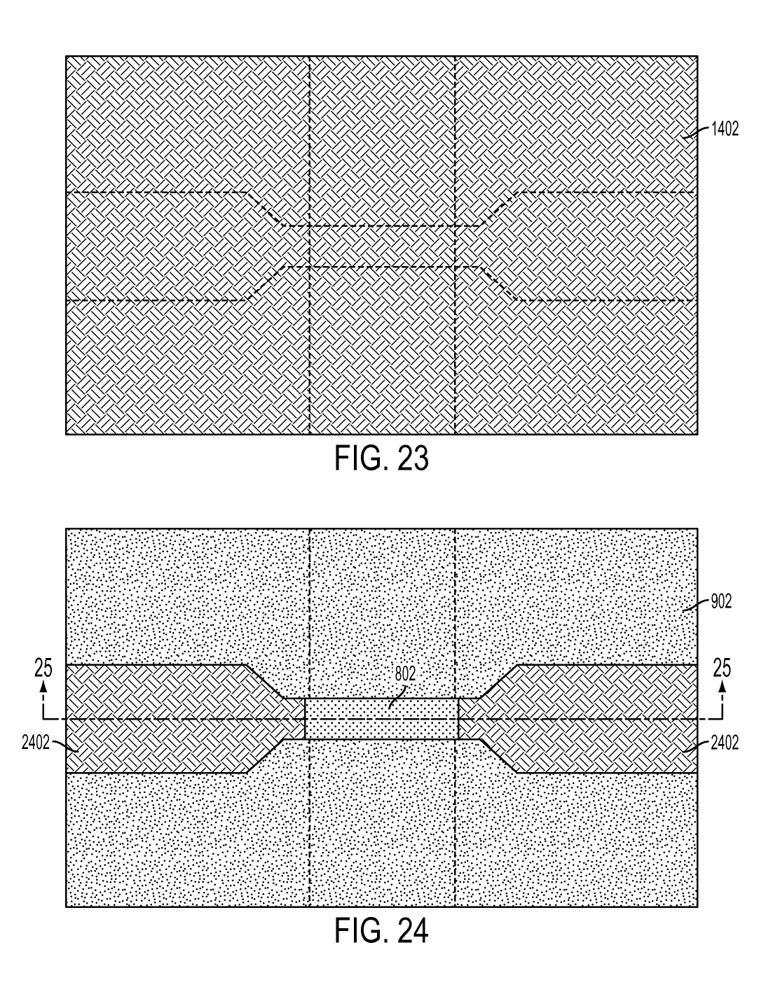

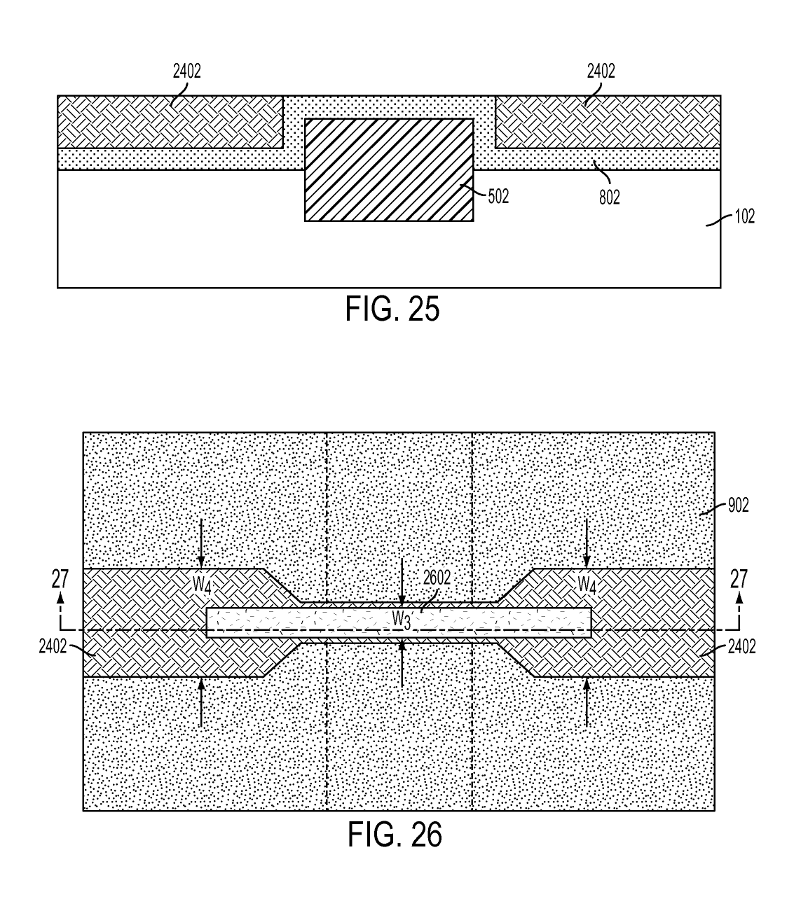

FIG. 24 illustrates a top view following a planarization process, such as, for example, CMP. The planarization process removes exposed portions of the conductive layer 1402 and the insulator layer 902 to expose portions of the insulator layer and a portion of the spacer layer 802 that is above the field line 502. The planarization process defines conductive strap portions 2402 that are separated from each other by the capping layer 802 and the field line 502. FIG. 25 illustrates a cut away view along the line 25 (of FIG. 24).

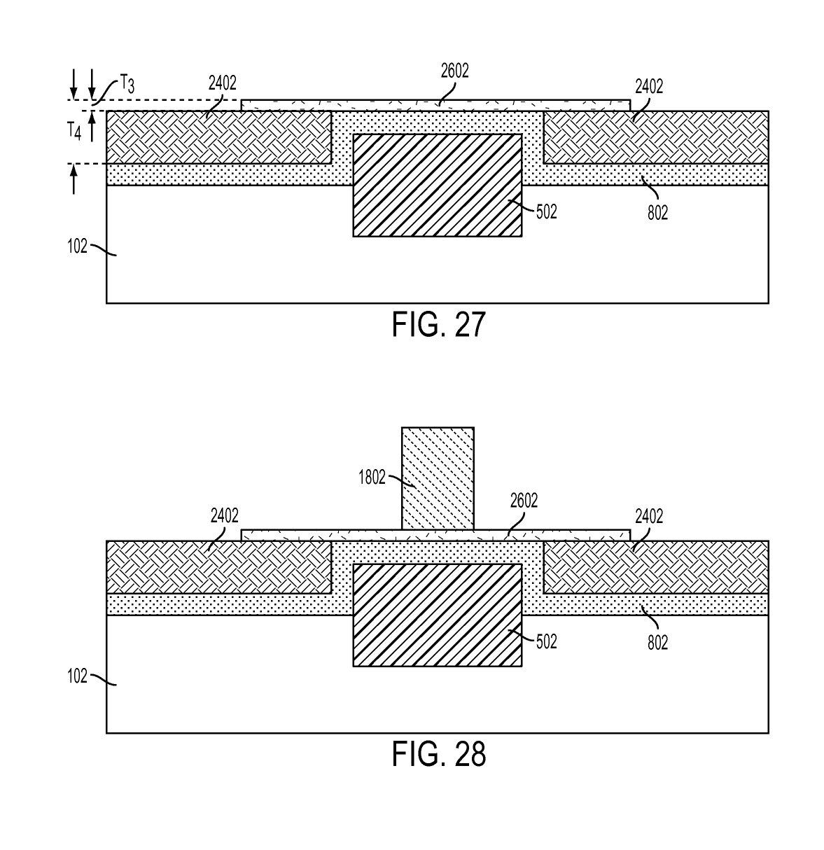

FIG. 26 illustrates a top view of the resultant structure following the formation of a conductive connector portion 2602 that contacts the conductive strap portions 2402 and provides a current path between the conductive strap portions 2402. The conductive connector portion 2602 may be formed by, for example, depositing a layer of conductive material such as, for example, Al, Cu, Ag, or Au over exposed portions of the insulator layer 902 and the conductive strap portions 2402. The conductive material may be deposited at a desired thickness (T₃). A suitable photolithographic patterning and etching process may be performed to pattern the conductive connector portion 2602 such that the conductive connector portion 2602 has a width (W₃). In the illustrated embodiment, the conductive strap portions 2402 have a width (W₄), where W₃<W₄. FIG. 27 illustrates a cut away view along the line 27 (of FIG. 26). The conductive connector portion 2602 has a thickness (T₃) and the conductive strap portions 2402 have a thickness (T₄) in distal regions above the substrate 102, where T₃<T₄.

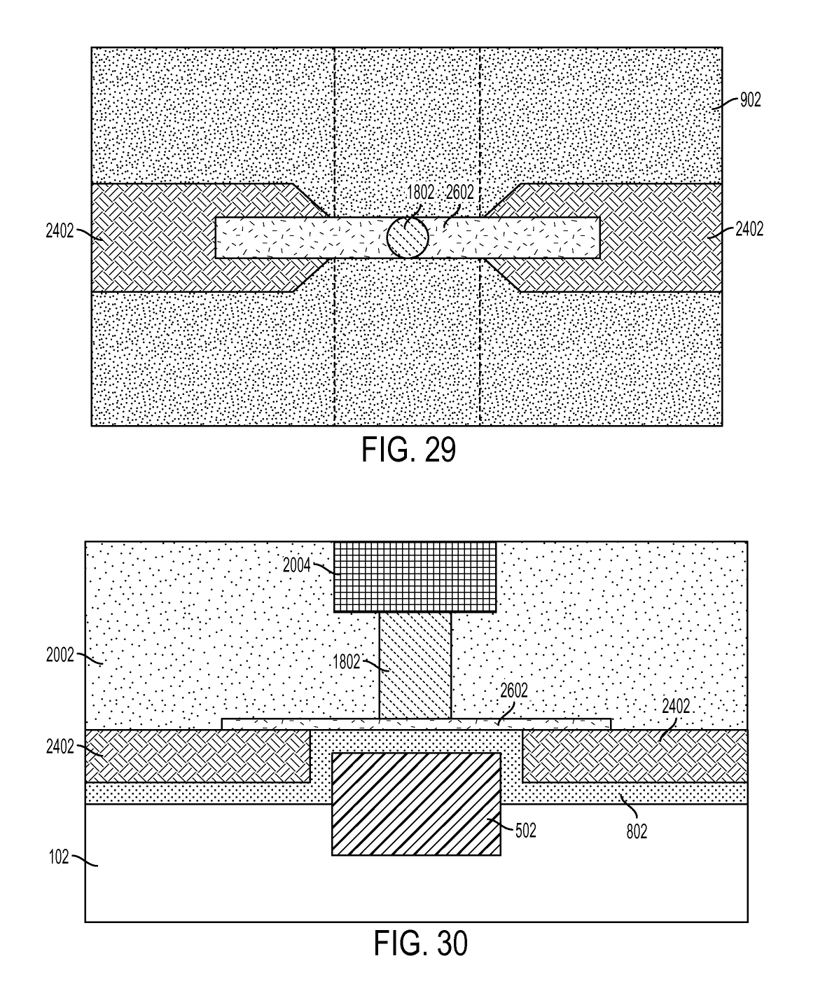

FIG. 28 illustrates a side view of the formation of an MRAM device stack 1802 on the conductive connector portion 2602. FIG. 29 illustrates a top view of FIG. 28.

FIG. 30 illustrates the resultant structure following the formation of a capping layer 2002 and a conductive electrode 2004 in a similar manner as discussed above in FIG. 20. The resultant MRAM device includes a current path defined by the conductive connector portion 2602 and the conductive strap portions 2402. The conductive connector portion 2602 defines a cross sectional area proximate to the MRAM device stack 1802 that is less than the cross sectional areas of the conductive strap portions 2402.

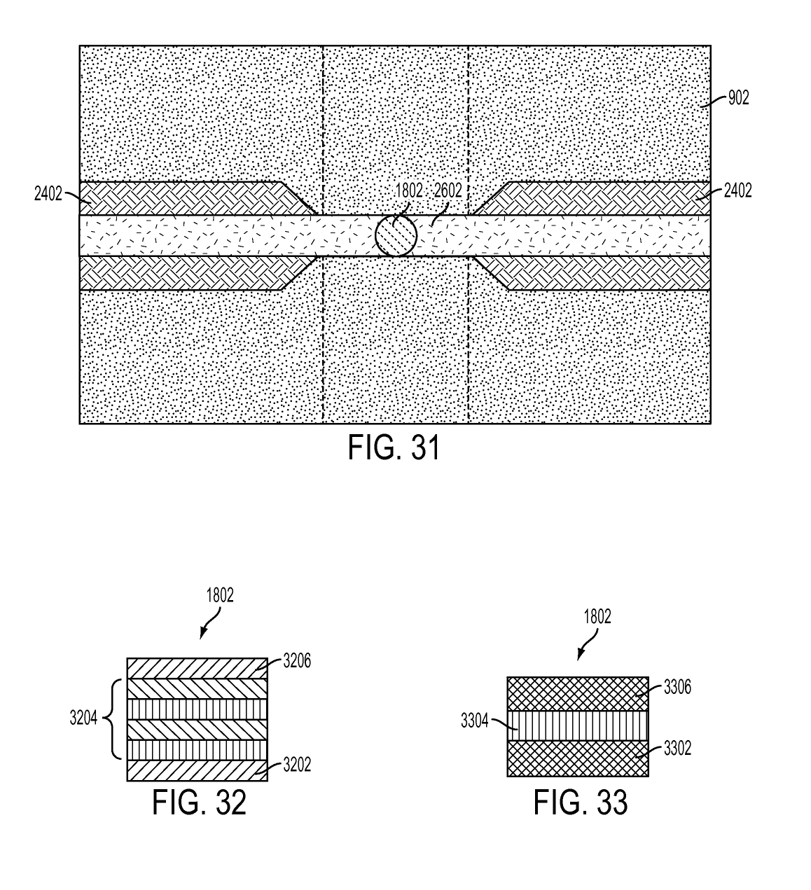

FIG. 31 illustrates an alternate exemplary embodiment of the conductive connector portion 3102 that is similar to the conductive connector portion 2602 (of FIG. 26), but has been patterned to extend along the longitudinal axis of the conductive strap portions 2402.

FIG. 32 illustrates an exemplary embodiment of an MRAM device stack 1802. The illustrated embodiment includes, for example, an anti-ferromagnetic portion 3202 that may be disposed on, for example, the conductive connector portion 2602 (of FIG. 28) or the conductive strap portion 1502 (of FIG. 18). A magnetic portion 3204 may be disposed on the anti-ferromagnetic portion 3202. The magnetic portion 3204 may include any number of layers of suitable materials to define a magnetic portion 3204 having desired properties. A second anti-ferromagnetic portion 3206 may be disposed on the magnetic portion 3204. The conductive electrode 2004 (of FIG. 20) may be arranged in contact or proximate to the second anti-ferromagnetic portion 3206.

FIG. 33 illustrates another exemplary embodiment of an MRAM device stack 1802. The illustrated embodiment includes, for example, a magnetic portion 3302 such as for example, Co or Fe, that may be disposed on, for example, the conductive connector portion 2602 (of FIG. 28) or the conductive strap portion 1502 (of FIG. 18). A tunnel barrier portion 3304 such as, for example, MgO is disposed on the magnetic portion 3302. A second magnetic portion 3306 is disposed on the tunnel barrier portion 3304. The conductive electrode 2004 (of FIG. 20) may be arranged in contact or proximate to the second magnetic portion 3306.

The methods and resultant structures described herein offer a current path having a reduced cross sectional area proximate to the MRAM device stack. Such a reduced cross sectional area increases the current density proximate to the MRAM device stack, and may be used to increase the thermal heating of an MRAM device proximate to the MRAM device stack or optimize other magnetic effects affected by increased current density proximate to the MRAM device stack. The methods described above offer a substantially self-aligned fabrication method.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1. A method for fabricating a spintronic cell, the method comprising:
forming a cavity in a substrate;
forming a wire in the cavity;
depositing a spacer layer over exposed portions of the substrate and the conductive field line;
depositing a layer of conductive material on a portion of the spacer layer;
removing portions of the layer of conductive material to define a conductive strap portion, wherein the conductive strap portion has a first distal region a second distal region and a medial region arranged therebetween, wherein the medial region has a cross sectional area that is less than a cross sectional area of the first distal region and a cross sectional area of the second distal region; and
forming an spintronic device stack on the conductive strap portion above the conductive field line.

2. The method of claim 1, wherein prior to depositing the layer of conductive material on the portion of the spacer layer, the method further includes:
depositing a first insulator layer over the spacer layer; and
patterning and etching to remove portions of the first insulator layer to expose portions of the spacer layer and define a cavity in the first insulator layer.

3. The method of claim 1, wherein the substrate includes an insulator material.

4. The method of claim 1, wherein the cavity in the substrate is formed by:
patterning a photolithographic resist layer on the substrate; and
etching to remove exposed portions of the substrate.

5. The method of claim 1, wherein the forming the wire in the cavity comprises:
depositing a layer of conductive material over exposed portions of the substrate;
performing a planarization process to remove portions of the layer of conductive material and expose portions of the substrate; and
etching to remove portions of the exposed portions of the substrate and expose sidewalls of the conductive field line.

6. The method of claim 5, wherein the spacer layer is formed conformally over the exposed portions of the substrate, the sidewalls of the conductive field line, and a top portion of the conductive field line.

7. The method of claim 1, wherein the spacer layer includes an insulator material.

8. The method of claim 1, wherein the spintronic device stack is a portion of a magnetic tunnel junction device.

9. The method of claim 1, wherein the spintronic device stack is a portion of a thermally assisted spintronic device.

10. The method of claim 1, wherein the spacer layer includes a nitride material and the first insulator layer includes an oxide material.

11. A method for fabricating a spintronic cell, the method comprising:
forming a cavity in a substrate;
forming a wire in the cavity;
depositing a spacer layer over exposed portions of the substrate and the conductive field line;
depositing a first insulator layer over the spacer layer;
patterning and etching to remove portions of the first insulator layer to expose portions of the spacer layer and define a cavity in the first insulator layer;
depositing a layer of conductive material in the cavity and over exposed portions of the first insulator layer;
removing portions of the conductive material to expose portions of the insulator layer and the spacer layer, and define a first conductive strap portion and a second conductive strap portion;
depositing a second layer of conductive material on exposed portions of the insulator layer, the spacer layer, the first conductive strap portion and the second conductive strap portion;
patterning the second layer of conductive material to expose portions of the insulator layer, the first conductive strap portion and the second conductive strap portion; and to define a conductive connector portion that electrically connects the first conductive strap portion with the second conductive strap portion; and
forming an spintronic device stack on the conductive connector portion above the conductive field line.

12. The method of claim 11, wherein the conductive connector portion has a cross sectional area that is less than a cross sectional area of the first conductive strap portion and the second conductive strap portion.

13. The method of claim 11, wherein the forming the wire in the cavity comprises:
depositing a layer of conductive material over exposed portions of the substrate;
performing a planarization process to remove portions of the layer of conductive material and expose portions of the substrate; and
etching to remove portions of the exposed portions of the substrate and expose sidewalls of the conductive field line.

14. The method of claim 13, wherein the spacer layer is formed conformally over the exposed portions of the substrate, the sidewalls of the conductive field line, and a top portion of the conductive field line.

15.-20. (canceled)
